(19) United States
(12) Patent Application Publication
(10) Pub. No.: US 2025/0318283 A1
(43) Pub. Date: Oct. 9, 2025

(54) SOLAR MODULE, PHOTOVOLTAIC APPARATUS, AND METHOD FOR PROCESSING SOLAR MODULE

(71) Applicant: SHENZHEN HELLO TECH ENERGY CO., LTD, Shenzhen (CN)

(72) Inventors: Hongyang GU, Shenzhen (CN); Zhongwei SUN, Shenzhen (CN); Yanjun ZHU, Shenzhen (CN); Minhuan ZHANG, Shenzhen (CN); Huajun YU, Shenzhen (CN)

(21) Appl. No.: 19/243,749

(22) Filed: Jun. 20, 2025

Related U.S. Application Data
(63) Continuation of application No. PCT/CN2025/070225, filed on Jan. 2, 2025.

(30) Foreign Application Priority Data
Jun. 6, 2024 (CN) 202410732397.7

(51) Int. Cl. H10F 19/80

(52) U.S. Cl. CPC H10F 19/807

(57) ABSTRACT

A solar module, a photovoltaic apparatus and a method for processing a solar module are disclosed. The solar module includes a solar cell assembly, a first protective layer, and a second protective layer. The solar cell assembly has a first surface and a second surface opposite to each other. The first protective layer is light-transmissive. The first surface faces towards the first protective layer. The first protective layer has a curved surface. The second surface faces towards the second protective layer. The first protective layer, the solar cell assembly, and the second protective layer are sequentially stacked together. The second protective layer having a curved surface. A distance D1 between an edge of the solar cell assembly and an edge of the first protective layer adjacent to the edge of the solar cell assembly ranges from 10 mm to 50 mm.

### CROSS-REFERENCE TO RELATED APPLICATIONS

This application is a continuation application of International Application No. PCT/CN2025/070225, filed on Jan. 2, 2025, which claims priority to and benefits of Chinese Patent Application No. 202410732397.7, filed with China National Intellectual Property Administration on Jun. 6, 2024, the entire disclosures of which are incorporated herein by reference.

### FIELD

The present disclosure relates to the technical field of photovoltaic apparatuses, and particularly, to a solar module, a photovoltaic apparatus, and a method for processing a solar module.

### BACKGROUND

A photovoltaic product 2′ having a curved surface in the related art is laminated by a laminator. As illustrated in FIG. 1, the laminator includes a plurality of lamination components 1′. The photovoltaic product 2′ is clamped by an upper lamination component 1′ and a lower lamination component 1′ and subjected to pressure for lamination. However, an edge part of the photovoltaic product 2′ is greatly deformed due to a lamination principle of a silicone bag laminator. This leads to an uneven stress distribution on the edge part, which is prone to hidden cracks.

### SUMMARY

The present disclosure aims to solve at least one of the technical problems in the related art.

To this end, a first object of the present disclosure is to provide a solar module.

A second object of the present disclosure is to provide a photovoltaic apparatus.

A third object of the present disclosure is to provide a method for processing a solar module.

To achieve at least one of the above objects, according to a first aspect of the present disclosure, a solar module is provided. The solar module includes a solar cell assembly, a first protective layer, and a second protective layer. The solar cell assembly is configured to convert light energy into electrical energy. The solar cell assembly has a first surface and a second surface opposite to each other. The first surface is capable of receiving light. The first protective layer is light-transmissive. The first surface of the solar cell assembly faces towards the first protective layer. The first protective layer has a curved surface. The second surface of the solar cell assembly faces towards the second protective layer. The first protective layer, the solar cell assembly, and the second protective layer are sequentially stacked together. The second protective layer has a curved surface. The solar cell assembly and the first protective layer are projected onto a projection plane in a stacking direction. On the projection plane, a projection area of the solar cell assembly is located within a projection area of the first protective layer with a distance D1 between an edge of the solar cell assembly and an edge of the first protective layer adjacent to the edge of the solar cell assembly ranging from 10 mm to 50 mm.

The present disclosure provides the solar module, which includes the solar cell assembly, the first protective layer, and the second protective layer. The solar module is configured to receive light and convert light energy into the electrical energy, and each of the first protective layer and the second protective layer is configured to protect a solar cell.

Specifically, the solar cell assembly has the first surface and the second surface opposite to each other. The first surface is capable of receiving light, enabling the solar cell assembly to convert light energy into the electrical energy and thus generate power. The first protective layer is located on the first surface of the solar cell assembly. Since the first protective layer is light-transmissive, the light can pass through the first protective layer to reach the first surface of the solar cell assembly. Since the first surface of the solar cell assembly faces towards the first protective layer, the light passes through the first protective layer and then reaches the first surface of the solar cell assembly. The solar cell assembly is configured to receive the light and convert the light energy into the electrical energy, enabling the solar module to generate the power. The second protective layer is configured to further protect the solar cell assembly. The second protective layer is located on the second surface of the solar cell assembly, and the second surface of the solar cell assembly faces towards the second protective layer. In this way, the solar cell assembly can be further protected by the second protective layer. The first protection layer, the solar cell assembly, and the second protection layer are sequentially stacked together. By providing the solar cell assembly between the first protection layer and the second protection layer, the solar cell assembly can be protected by the first protection layer and the second protection layer. The first protective layer is made of tempered glass, and the second protective layer may be made of tempered glass or polyethylene terephthalate polyester resin (PET).

Further, each of the first protective layer and the second protective layer has the curved surface. The solar cell assembly, the first protective layer, and the second protective layer are laminated by a silicone bag laminator to form the solar module. Since each of the first protective layer and the second protective layer has the curved surface, the solar cell assembly is deformed along with bending of the surface of the first protective layer and the surface of the second protective layer during a lamination. The solar cell assembly is prone to hidden cracks after being deformed under pressure. In order to lower a probability of hidden cracks in the solar cell, a size relationship between the solar cell assembly and the first protective layer is limited in the present disclosure.

Specifically, the solar cell assembly and the first protective layer are projected onto the projection plane in a stacking direction. On the projection plane, the projection area of the solar cell assembly is located within the projection area of the first protective layer with the distance D1 between the edge of the solar cell assembly and the edge of the first protective layer adjacent to the edge of the solar cell assembly ranging from 10 mm to 50 mm. It can be understood that stress on an edge of the solar cell assembly is related to a distance between a solar cell group and the edge of the first protective layer adjacent to the solar cell group. The stress on the edge of the solar cell assembly decreases as the distance between the solar cell group and the edge of the first protective layer adjacent to the solar cell group increases, and the stress on the edge of the solar cell assembly increases as the distance between the solar cell group and the edge of the first protective layer adjacent to the solar cell group decreases. By limiting the distance between any solar cell group and the edge of the first protective layer adjacent to any solar cell group to within the range of 10 mm to 50 mm, the stress on the edge of the solar cell assembly can be reduced, and thus the probability of the hidden cracks in the solar cell assembly can be lowered. In a possible technical solution, the distance between any solar cell group and the edge of the first protective layer adjacent to any solar cell group is 25 mm.

In the present disclosure, by limiting the distance between any solar cell group and the edge of the first protective layer adjacent to any solar cell group to within the range of 10 mm to 50 mm, the stress on the edge of the solar cell assembly can be reduced, and thus the probability of the hidden cracks in the solar cell assembly can be lowered. As a result, a yield rate of the solar module as well as stability and reliability of the product are improved.

According to the solar module mentioned above in the present disclosure, it may also have the following distinguishing technical features.

In some technical solutions, the solar cell assembly includes a plurality of solar cell groups. Any one of the plurality of solar cell groups includes a plurality of solar cells. For each of the plurality of solar cell groups: two adjacent solar cells overlap each other with an overlapping dimension D2 ranging from 0 mm to 0.5 mm; or two adjacent solar cells are spaced apart by a spacing D3 ranging from 0 mm to 5 mm.

In this technical solution, the structure and the size of the solar cell assembly are limited. The solar cell assembly includes the plurality of solar cell groups. Any one of the plurality of solar cell groups includes the plurality of solar cells. The solar cell may be a crystalline silicon solar cell. In a possible technical solution, the plurality of solar cell groups are sequentially arranged in a first direction, and the plurality of solar cells in any one of the plurality of solar cell groups are sequentially arranged in a second direction perpendicular to the first direction. The solar module according to the present disclosure may be processed by the silicone bag laminator. Specifically, the silicone bag laminator includes a plurality of lamination components. When processing the solar module, the first protective layer, the solar cell assembly, and the second protective layer are sequentially stacked between the plurality of lamination components. Under an action of a vacuum negative pressure, the plurality of lamination components apply opposite pressure to the first protective layer, the solar cell assembly, and the second protective layer to laminate the first protective layer, the solar cell assembly, and the second protective layer. The solar cells in the solar cell assembly are prone to the hidden cracks after being deformed under the pressure. In order to lower the probability of the hidden cracks in the solar cells, a distance between the individual solar cells in the solar cell assembly is limited in the present disclosure.

Further, for each of the plurality of solar cell groups, the two adjacent solar cells overlap each other or have the spacing. Specifically, when the two adjacent solar cells overlap each other, an overlapping dimension D2 ranges from 0 mm to 0.5 mm. When the two adjacent solar cells are spaced apart by a spacing D3, the spacing D3 ranges from 0 mm to 5 mm. By limiting the size of the overlapping part between the two adjacent solar cells to within the range of 0 mm to 0.5 mm, or limiting the spacing between the two adjacent solar cells to within the range of 0 mm to 5 mm, the probability of the hidden cracks in the solar cells due to the stress can be lowered. In a possible technical solution, the distance between any two adjacent solar cells is 0.5 mm.

In the present disclosure, by limiting the size of the overlapping part between the two adjacent solar cells to within the range of 0 mm to 0.5 mm, or limiting the spacing between the two adjacent solar cells to within the range of 0 mm to 5 mm, the solar cell is prevented from being subjected to excessive local stress, and thus the probability of the hidden cracks in the solar cell is lowered. As a result, the yield rate of the solar module as well as the stability and the reliability of the product are improved.

In some technical solutions, a distance D4 between any two adjacent solar cell groups ranges from 3 mm to 20 mm.

In this technical solution, a distance D4 between two adjacent solar cell groups is limited. Specifically, the distance between any two adjacent solar cell groups ranges from 3 mm to 20 mm. It can be understood that overall rigidity of the solar cell assembly is related to the spacing between the two adjacent solar cell groups. As the spacing between the two adjacent solar cell groups decreases, the rigidity of the solar cell assembly increases, making it more difficult for the solar cell assembly to deform along with the surface of the first protective layer and the surface of the second protective layer. Conversely, as the spacing between the two adjacent solar cell groups increases, the rigidity of the solar cell assembly decreases, making it easier for the solar cell assembly to deform along with the surface of the first protective layer and the surface of the second protective layer. By limiting the distance between any two adjacent solar cell groups to within the range of 3 mm to 20 mm, the rigidity of the solar cell assembly can meet processing requirements. While ensuring the overall rigidity of the solar module, the difficulty in the deformation of the solar cell assembly is reduced, and thus the probability of the hidden cracks in the solar cell assembly is lowered. In a possible technical solution, the distance between any two adjacent solar cell groups is 3 mm.

In the present disclosure, by limiting the distance between any two adjacent solar cell groups within the range of 3 mm to 20 mm, the difficulty in the deformation of the solar cell assembly can be reduced while ensuring the overall rigidity of the solar module, and thus the probability of the hidden cracks in the solar cell assembly is lowered. As a result, the yield rate of the solar module as well as the stability and the reliability of the product are improved.

In some technical solutions, each of the plurality of solar cells has a curved surface.

In this technical solution, the solar cell is further limited. Specifically, each of the solar cell, the first protective layer, and the second protective layer has a curved surface. As a result, the solar module is formed as a curved product. In this way, it is possible to not only improve aesthetically pleasing of the solar module but also make the solar module applicable to more types of photovoltaic apparatuses.

In some technical solutions, the solar module further includes a first adhesive film layer and a second adhesive film layer. The first adhesive film layer is located between the solar cell assembly and the first protective layer. The first adhesive film layer is configured to bond the solar cell assembly and the first protective layer. The first adhesive film layer being light-transmissive. The second adhesive film layer is located between the solar cell assembly and the second protective layer. The second adhesive film layer is configured to bond the solar cell assembly and the second protective layer.

In this technical solution, the structure of the solar module is further limited. The solar module further includes the first adhesive film layer and the second adhesive film layer. The first adhesive film layer and the second adhesive film layer are configured to bond the first protective layer, the solar cell assembly and the second protective layer into one piece. Specifically, the first adhesive film layer is located between the solar cell assembly and the first protective layer and is configured to bond the solar cell assembly and the first protective layer. Moreover, since the first adhesive film layer is light-transmissive, the light can pass through the first protective layer and the first adhesive film layer to reach the solar cell assembly, enabling the solar cell assembly to convert the light energy into the electrical energy and thus generate the power. The second adhesive film layer is located between the solar cell assembly and the second protective layer and is configured to bond the solar cell assembly and the second protective layer.

Each of the first adhesive film layer and the second adhesive film layer may be made of ethylene vinyl acetate polymer (EVA), polyethylene (POE), polyvinyl butyral (PVB), or organic silicone or the like.

By providing the first adhesive film layer and the second adhesive film layer in the solar module, the first protective layer and the solar cell assembly can be bonded by the first adhesive film layer, and the second protective layer and the solar cell assembly can be bonded by the second adhesive film layer. Thus, the first protective layer, the solar cell assembly, and the second protective layer are formed into a whole.

In some technical solutions, the second surface is capable of receiving light, and the second protective layer and the second adhesive film layer are light-transmissive.

In this technical solution, the solar cell assembly, the second protective layer, and the second adhesive film layer are further limited. Specifically, the second surface of the solar cell assembly is capable of receiving light, and the second protective layer and the second adhesive film layer are light-transmissive. In this way, the light can pass through the second protective layer and the second adhesive film layer, and then reach the second surface of the solar cell assembly. Since the second surface of the solar cell assembly is capable of receiving light, the solar cell assembly can achieve bifacial power generation.

By configuring the second protective layer and the second adhesive film layer to be light-transmissive and the second surface of the solar cell assembly to be capable of receiving light, the solar cell assembly can achieve the bifacial power generation, making the solar module a bifacial power generation product.

A second aspect of the present disclosure further provides a photovoltaic apparatus. The photovoltaic apparatus includes the solar module according to the first aspect of the present disclosure.

The photovoltaic apparatus according to the second aspect of the present disclosure includes the solar module according to the first aspect of the present disclosure, and thus has all the beneficial effects of the solar module.

A third aspect of the present disclosure also provides a method for processing a solar module. The solar module is laminated by a laminator, and the laminator includes a plurality of lamination components. The method for processing the solar module includes: sequentially stacking a first protective layer, a first adhesive film layer, a solar cell assembly, a second adhesive film layer, and a second protective layer between the plurality of lamination components in a top-to-bottom direction, each of the first protective layer and the second protective layer having a curved surface, and the solar cell assembly and the first protective layer being projected onto a projection plane in a stacking direction. On the projection plane, a projection area of the solar cell assembly is located within a projection area of the first protective layer with a distance D1 between an edge of the solar cell assembly and an edge of the first protective layer adjacent to the edge of the solar cell assembly ranging from 10 mm to 50 mm; and laminating, by the plurality of lamination components, the first protective layer, the first adhesive film layer, the solar cell assembly, the second adhesive film layer, and the second protective layer to form the solar module.

The method for processing the solar module according to the present disclosure is used to process the solar module. The solar module is laminated by the laminator, and the laminator includes the plurality of lamination components. The laminator is configured to apply pressure to the first protective layer, the first adhesive film layer, the solar cell assembly, the second adhesive film layer, and the second protective layer through the plurality of lamination components to form the solar module. Specifically, the first protective layer, the first adhesive film layer, the solar cell assembly, the second adhesive film layer, and the second protective layer are sequentially stacked between the plurality of lamination components in the top-to-bottom direction. Then, the first protective layer, the first adhesive film layer, the solar cell assembly, the second adhesive film layer, and the second protective layer are laminated by the lamination components to form the solar module. During the lamination, the first protective layer is bonded to the first surface of the solar cell assembly through the first adhesive film layer, and the second protective layer is bonded to the second surface of the solar cell assembly through the second adhesive film layer, to form the solar module.

Further, each of the first protective layer and the second protective layer has the curved surface, and the solar cell assembly, the first protective layer, and the second protective layer are laminated by the silicone bag laminator to form the solar module. Since each of the first protective layer and the second protective layer has the curved surface, the solar cell assembly is deformed along with bending of the surfaces of the first protective layer and the second protective layer during the lamination. The solar cell assembly is prone to hidden cracks after being deformed under pressure. In order to lower a probability of hidden cracks in the solar cell, a size relationship between the solar cell assembly and the first protective layer is defined in the present disclosure.

Specifically, the solar cell assembly and the first protective layer are projected onto the projection plane in the stacking direction. On the projection plane, the projection area of the solar cell assembly is located within the projection area of the first protective layer with the distance D1 between the edge of the solar cell assembly and the edge of the first protective layer adjacent to the edge of the solar cell assembly ranging from 10 mm to 50 mm. It can be understood that stress on an edge of the solar cell assembly is related to a distance between a solar cell group and the edge of the first protective layer adjacent to the solar cell group. The stress on the edge of the solar cell assembly decreases as the distance between the solar cell group and the edge of the first protective layer adjacent to the solar cell group increases, and the stress on the edge of the solar cell assembly increases as the distance between the solar cell group and the edge of the first protective layer adjacent to the solar cell group decreases. By limiting the distance between any solar cell group and the edge of the first protective layer adjacent to any solar cell group to within the range of 10 mm to 50 mm, the stress on the edge of the solar cell assembly can be reduced, and thus the probability of the hidden cracks in the solar cell assembly can be lowered. In a possible technical solution, the distance between any solar cell group and the edge of the first protective layer adjacent to any solar cell group is 25 mm.

In the present disclosure, by limiting the distance between any solar cell group and the edge of the first protective layer adjacent to any solar cell group to within the range of 10 mm to 50 mm, the stress on the edge of the solar cell assembly can be reduced, and thus the probability of the hidden cracks in the solar cell assembly can be lowered. As a result, the yield rate of the solar module as well as the stability and the reliability of the product are improved.

In some technical solutions, the laminating, by the plurality of lamination components, the first protective layer, the first adhesive film layer, the solar cell assembly, the second adhesive film layer, and the second protective layer includes: controlling a heating device of the laminator to heat an interior of the laminator; and controlling an air extraction device of the laminator to evacuate the interior of the laminator, to allow the plurality of lamination components to laminate the first protective layer, the first adhesive film layer, the solar cell assembly, the second adhesive film layer, and the second protective layer under a vacuum negative pressure.

In this technical solution, the step of laminating the first protective layer, the first adhesive film layer, the solar cell assembly, the second adhesive film layer, and the second protective layer by the plurality of lamination components is limited. Specifically, the heating device of the laminator is controlled to heat the interior of the laminator first, and then the air extraction device of the laminator is controlled to evacuate the interior of the laminator, to allow the plurality of lamination components to laminate the first protective layer, the first adhesive film layer, the solar cell assembly, the second adhesive film layer, and the second protective layer under the vacuum negative pressure. The first adhesive film layer and the second adhesive film layer are melted after being heated, and then the first protective layer and the second protective layer are respectively bonded to two sides of the solar cell assembly through the first adhesive film layer and the second adhesive film layer under the pressure of the plurality of lamination components to form the solar module.

In some technical solutions, the solar cell assembly includes a plurality of solar cell groups. Any one of the plurality of solar cell groups includes a plurality of solar cells. For each of the plurality of solar cell groups: two adjacent solar cells overlap each other with an overlapping dimension D2 ranging from 0 mm to 0.5 mm, or two adjacent solar cells are spaced apart by a spacing D3 ranging from 0 mm to 5 mm; and a distance D4 between any two adjacent solar cell groups ranges from 3 mm to 20 mm.

In this technical solution, the structure and the related size of the solar cell assembly are limited. The solar cell assembly includes the plurality of solar cell groups. Any one of the plurality of solar cell groups includes the plurality of solar cells. For each of the plurality of solar cell groups, the two adjacent solar cells overlap each other with the overlapping dimension D2 ranging from 0 mm to 0.5 mm; or the two adjacent solar cells are spaced apart by the spacing D3 ranging from 0 mm to 5 mm. The solar cell may be a crystalline silicon solar cell. In a possible technical solution, the plurality of solar cell groups are sequentially arranged in a first direction, and the plurality of solar cells in any one of the plurality of solar cell groups are sequentially arranged in a second direction perpendicular to the first direction. The solar module according to the present disclosure may be processed by the silicone bag laminator. Specifically, the silicone bag laminator includes a plurality of lamination components. When processing the solar module, the first protective layer, the solar cell assembly, and the second protective layer are sequentially stacked between the plurality of lamination components. Under the action of vacuum negative pressure, the plurality of lamination components apply opposite pressure to the first protective layer, the solar cell assembly, and the second protective layer to laminate the first protective layer, the solar cell assembly, and the second protective layer. The solar cells in the solar cell assembly are prone to the hidden cracks after being deformed under the pressure. In order to lower the probability of the hidden cracks in the solar cells, a distance between the individual solar cells in the solar cell assembly is limited in the present disclosure.

Further, for each of the plurality of solar cell groups, the two adjacent solar cells overlap each other or have the spacing. Specifically, when the two adjacent solar cells overlap each other, an overlapping dimension D2 ranges from 0 mm to 0.5 mm. When the two adjacent solar cells are spaced apart by a spacing D3, the spacing D3 ranges from 0 mm to 5 mm. By limiting the size of the overlapping part between the two adjacent solar cells to within the range of 0 mm to 0.5 mm, or limiting the spacing between the two adjacent solar cells to within the range of 0 mm to 5 mm, the probability of the hidden cracks in the solar cells due to the stress can be lowered. In a possible technical solution, the distance between any two adjacent solar cells is 0.5 mm.

Furthermore, a distance D4 between any two adjacent solar cell groups among the plurality of solar cell groups ranges from 3 mm to 20 mm. It can be understood that overall rigidity of the solar cell assembly is related to the spacing between the two adjacent solar cell groups. As the spacing between the two adjacent solar cell groups decreases, the rigidity of the solar cell assembly increases, making it more difficult for the solar cell assembly to deform along with the surface of the first protective layer and the surface of the second protective layer. Conversely, as the spacing between the two adjacent solar cell groups increases, the rigidity of the solar cell assembly decreases, making it easier for the solar cell assembly to deform along with the surface of the first protective layer and the surface of the second protective layer. By limiting the distance between any two adjacent solar cell groups to within the range of 3 mm to 20 mm, the rigidity of the solar cell assembly can meet processing requirements. While ensuring the overall rigidity of the solar module, the difficulty in the deformation of the solar cell assembly is reduced, and thus the probability of the hidden cracks in the solar cell assembly is lowered. In a possible technical solution, the distance between any two adjacent solar cell groups is 3 mm.

By limiting the size of the overlapping part between the two adjacent solar cells to within the range of 0 mm to 0.5 mm, or limiting the spacing between the two adjacent solar cells to within the range of 0 mm to 5 mm, the solar cell is prevented from being subjected to excessive local stress, and thus the probability of the hidden cracks in the solar cell is lowered. As a result, the yield rate of the solar module as well as the stability and the reliability of the product are improved. By limiting the distance between any two adjacent solar cell groups to within the range of 2 mm to 5 mm, the difficulty in the deformation of the solar cell assembly can be reduced while ensuring the overall rigidity of the solar module, and thus the probability of the hidden cracks in the solar cell assembly is lowered. As a result, the yield rate of the solar module as well as the stability and the reliability of the product are improved.

Additional aspects and advantages of the embodiments of present disclosure will be provided at least in part in the following description, or will become apparent in part from the following description, or can be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the accompanying drawings.

FIG. 1 shows a schematic diagram of a lamination of a photovoltaic product in the related art.

FIG. 2 shows a schematic diagram of a negative spacing between two adjacent solar cells according to an embodiment of the present disclosure.

FIG. 3 shows a schematic diagram of a positive spacing between two adjacent solar cells according to an embodiment of the present disclosure.

FIG. 4 shows a first schematic diagram of a relative position between two adjacent solar cell groups according to an embodiment of the present disclosure.

FIG. 5 shows a second schematic diagram of a relative position between two adjacent solar cell groups according to an embodiment of the present disclosure.

FIG. 6 shows an exploded view of a solar module according to an embodiment of the present disclosure.

FIG. 7 shows a schematic diagram of a solar cell assembly according to an embodiment of the present disclosure.

FIG. 8 shows a first schematic flowchart of a method for processing a solar module according to an embodiment of the present disclosure.

FIG. 9 shows a second schematic flowchart of a method for processing a solar module according to an embodiment of the present disclosure.

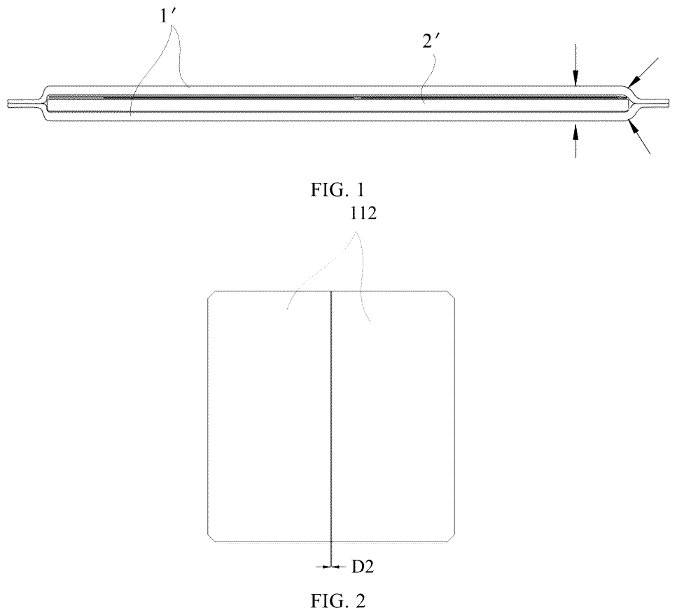

A correspondence between reference numerals and names of the components in FIG. 1 is as follows:
1′ laminate, 2′ photovoltaic product.

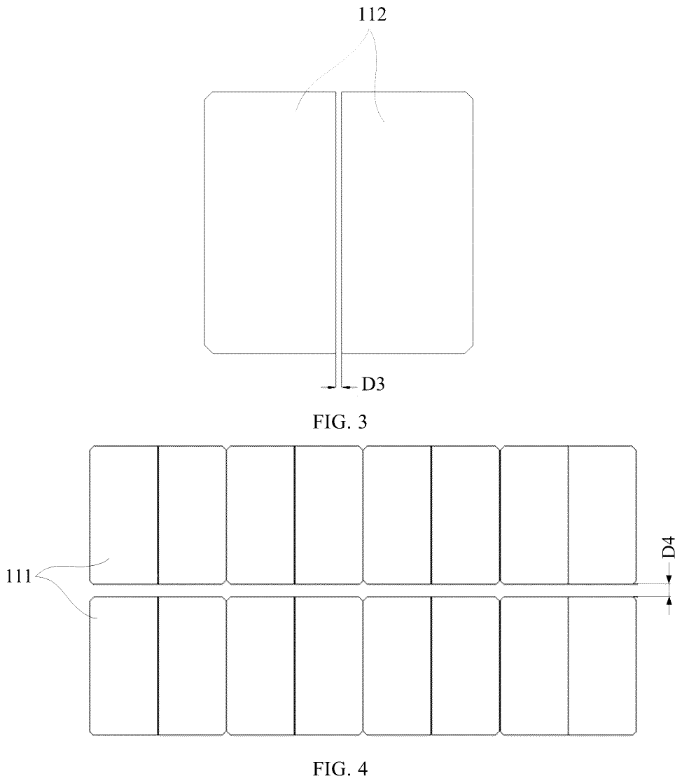

A correspondence between reference numerals and names of the components in FIGS. 2 to 7 is as follows:
100 solar module, 110 solar cell assembly, 111 solar cell group, 112 solar cell, 113 first surface, 114 second surface, 120 first protective layer, 130 second protective layer, 140 first adhesive film layer, 150 second adhesive film layer.

### DETAILED DESCRIPTION OF THE EMBODIMENTS

The embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain rather than limit the present disclosure.

Various embodiments or examples for implementing different structures of the embodiments of the present disclosure are provided below. To simplify the embodiments of the present disclosure, components and settings in specific examples are described below. Of course, they are merely exemplary and are not intended to limit the present disclosure. Moreover, the embodiments of the present disclosure may repeat reference numbers and/or reference letters in different examples. Such repetition is for purposes of simplicity and clarity and is in itself indicative of a relationship among the various embodiments and/or settings discussed. In addition, the present disclosure provides examples of various specific processes and materials, but those of ordinary skill in the art may recognize application of other processes and/or use of other materials.

A solar module 100, a photovoltaic apparatus, and a method for processing a solar module according to some embodiments of the present disclosure will be described below with reference to FIGS. 2 to 9.

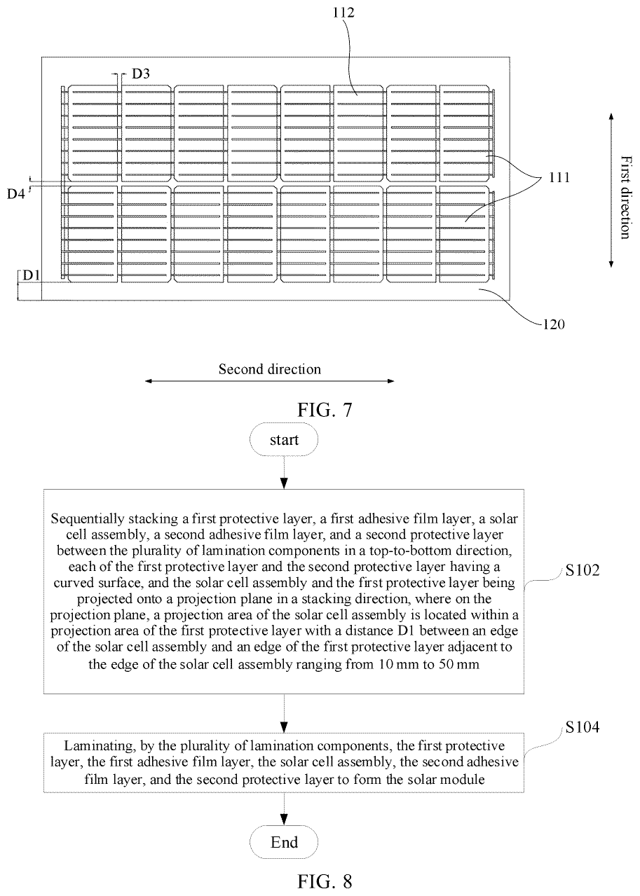

In an embodiment of the present disclosure, as shown in FIGS. 6 and 7, the present disclosure provides a solar module 100. The solar module 100 includes a solar cell assembly 110, a first protective layer 120, and a second protective layer 13. The solar cell assembly 110 is configured to convert light energy into electrical energy. The solar cell assembly 110 has a first surface 113 and a second surface 114 that face away from each other. The first surface 113 is capable of receiving light. The first protective layer 120 is light-transmissive. The first surface 113 of the solar cell assembly 110 faces towards the first protective layer 120. The first protective layer 120 has a curved surface. The second surface 114 of the solar cell assembly 110 faces towards the second protective layer 130. The first protective layer 120, the solar cell assembly 110, and the second protective layer 130 are sequentially stacked together. The second protective layer 130 has a curved surface. The solar cell assembly 110 and the first protective layer 120 are projected onto a projection plane in a stacking direction. On the projection plane, a projection area of the solar cell assembly 110 is located within a projection area of the first protective layer 120 with a distance D1 between an edge of the solar cell assembly 110 and an edge of the first protective layer 120 adjacent to the edge of the solar cell assembly 110 ranging from 10 mm to 50 mm.

The present disclosure provides the solar module 100, which includes the solar cell assembly 110, the first protective layer 120, and the second protective layer 130. The solar module 100 is configured to receive the light and convert the light energy into the electrical energy, and each of the first protective layer 120 and the second protective layer 130 is configured to protect the solar cell 112.

Specifically, the solar cell assembly 110 has the first surface 113 and the second surface 114 that face away from each other. The first surface 113 is capable of receiving light, enabling the solar cell assembly 110 to convert the light energy into the electrical energy and thus generate power. The first protection layer 120 is located on the first surface 113 of the solar cell assembly 110. Since the first protection layer 120 is light-transmissive, the light can pass through the first protection layer 120 to reach the solar cell assembly 110. Since the first surface 113 of the solar cell assembly 110 faces towards the first protective layer 120, the light passes through the first protective layer 120 and then reaches the first surface 113 of the solar cell assembly 110. The solar cell assembly 110 is configured to receive the light and convert the light energy into the electrical energy, enabling the solar module 100 to generate the power. The second protection layer 130 is configured to further protect the solar cell assembly 110. The second protection layer 130 is located on the second surface 114 of the solar cell assembly 110, and the second surface 114 of the solar cell assembly 110 faces towards the second protection layer 130. In this way, the solar cell assembly 110 can be further protected by the second protection layer 130. The first protection layer 120, the solar cell assembly 110, and the second protection layer 130 are sequentially stacked in the stacking direction. By providing the solar cell assembly 110 between the first protection layer 120 and the second protection layer 130, the solar cell assembly 110 can be protected by the first protection layer 120 and the second protection layer 130.

The first protective layer 120 is made of tempered glass, and the second protective layer 130 may be made of tempered glass or polyethylene terephthalate (PET).

Further, each of the first protective layer 120 and the second protective layer 130 has the curved surface. The solar cell assembly 110, the first protective layer 120, and the second protective layer 130 are laminated by a silicone bag laminator to form the solar module 100. Since each of the first protective layer 120 and the second protective layer 130 has the curved surface, the solar cell assembly 110 is deformed along with bending of the surface of the first protective layer 120 and the surface of the second protective layer 130 during a lamination. The solar cell assembly 110 is prone to hidden cracks after being deformed under pressure. In order to lower a probability of hidden cracks in the solar cell, a size relationship between the solar cell assembly 110 and the first protective layer 120 is limited in the present disclosure.

Specifically, the solar cell assembly 110 and the first protective layer 120 are projected onto the projection plane in the stacking direction. On the projection plane, the projection area of the solar cell assembly 110 is located within the projection area of the first protective layer with the distance D1 between the edge of the solar cell assembly 110 and the edge of the first protective layer 120 adjacent to the edge of the solar cell assembly 110 ranging from 10 mm to 50 mm. It can be understood that stress on the edge of the solar cell assembly 110 is related to a distance between a solar cell group and the edge of the first protective layer 120 adjacent to the solar cell group. The stress on the edge of the solar cell assembly 110 decreases as the distance between the solar cell group and the edge of the first protective layer 120 adjacent to the solar cell group increases, and the stress on the edge of the solar cell assembly 110 increases as the distance the solar cell group and the edge of the first protective layer 120 adjacent to the solar cell group decreases. By limiting the distance between any solar cell group and the edge of the first protective layer 120 adjacent to any solar cell group to within the range of 10 mm to 50 mm, the stress on the edge of the solar cell assembly 110 can be reduced, and thus the probability of the hidden cracks in the solar cell assembly 110 can be lowered. In a possible embodiment, the distance between any solar cell group and the edge of the first protection layer 120 adjacent to any solar cell group is 25 mm.

In the present disclosure, by limiting the distance between any solar cell group and the edge of the first protective layer 120 adjacent to any solar cell group to within the range of 10 mm to 50 mm, the stress on the edge of the solar cell assembly 110 can be reduced, and thus the probability of the hidden cracks in the solar cell assembly 110 can be lowered. As a result, a yield rate of the solar module 100 as well as stability and reliability of the product are improved. In some embodiments, as shown in FIGS. 2, 3, and 7, the solar cell assembly 110 includes a plurality of solar cell groups 111. Any one of the plurality of solar cell groups 111 includes a plurality of solar cells 112. For each of the plurality of solar cell groups, two adjacent solar cells 112 overlap each other with an overlapping dimension D2 ranging from 0 mm to 0.5 mm; or two adjacent solar cells 112 are spaced apart by a spacing D3 ranging from 0 mm to 5 mm.

In this embodiment, the structure and the size of the solar cell assembly 110 are limited. The solar cell assembly 110 includes the plurality of solar cell groups 111. Any one of the plurality of solar cell groups 111 includes the plurality of solar cells 112. The solar cell 112 may be a crystalline silicon solar cell. In a possible embodiment, the plurality of solar cell groups 111 are sequentially arranged in a first direction, and the plurality of solar cells 112 in any one of the plurality of solar cell groups 111 are sequentially arranged in a second direction perpendicular to the first direction. The solar module 100 according to the present disclosure may be processed by the silicone bag laminator. Specifically, the silicone bag laminator includes a plurality of lamination components. When processing the solar module 130 are sequentially stacked between the plurality of lamination components. Under an action of vacuum negative pressure, the plurality of lamination components apply opposite pressure to the first protective layer 120, the solar cell assembly 110, and the second protective layer 130 to laminate the first protective layer 120, the solar cell assembly 110, and the second protective layer 130. The solar cells 112 in the solar cell assembly 110 are prone to the hidden cracks after being deformed under the pressure. In order to lower the probability of the hidden cracks in the solar cells 112, a distance between the individual solar cells 112 in the solar cell assembly 110 is limited in the present disclosure.

Further, for each of the plurality of solar cell groups 111, the two adjacent solar cells 112 overlap each other or are spaced apart by the spacing. Specifically, as shown in FIG. 2, when the two adjacent solar cells 112 overlap each other, an overlapping dimension D2 ranges from 0 mm to 0.5 mm. As shown in FIG. 3, when the two adjacent solar cells 112 are spaced apart by a spacing D3, D3 ranges from 0 mm to 5 mm. By limiting the size of the overlapping part between the two adjacent solar cells 112 to within the range of 0 mm to 0.5 mm, or limiting the spacing between the two adjacent solar cells 112 to within the range of 0 mm to 5 mm, the probability of the hidden cracks in the solar cells 112 due to the stress can be lowered. In a possible embodiment, the distance between any two adjacent solar cells 112 is 0.5 mm.

In the present disclosure, by limiting the size of the overlapping part between the two adjacent solar cells 112 to within the range of 0 mm to 0.5 mm, or limiting the spacing between the two adjacent solar cells 112 to within the range of 0 mm to 5 mm, the solar cell 112 is prevented from being subjected to excessive local stress, and thus the probability of the hidden cracks in the solar cell 112 is lowered. As a result, the yield rate of the solar module 100 as well as the stability and the reliability of the product are improved.

In some embodiments, as shown in FIGS. 4, 5, and 7, a distance D4 between any two adjacent solar cell groups among the plurality of solar cell groups 111 ranges from 3 mm to 20 mm.

In this embodiment, a distance between two adjacent solar cell groups 111 is limited. Specifically, the distance D4 between any two adjacent solar cell groups 111 ranges from 3 mm to 20 mm. It can be understood that overall rigidity of the solar cell assembly 110 is related to a spacing between two adjacent solar cell groups 111. As the spacing between the two adjacent solar cell groups 111 decreases, the rigidity of the solar cell assembly increases, making it more difficult for the solar cell assembly 110 to deform along with the surface of the first protective layer 120 and the surface of the second protective layer. Conversely, as the spacing between the two adjacent solar cell groups 111 increases, the rigidity of the solar cell assembly 110 decreases, making it easier for the solar cell assembly 110 to deform along with the surface of the first protective layer 120 and the surface of the second protective layer. By limiting the distance between any two adjacent solar cell groups 111 to within the range of 3 mm to 20 mm, the rigidity of the solar cell assembly 110 can meet processing requirements. While ensuring the overall rigidity of the solar module 100, the difficulty in the deformation of the solar cell assembly 110 is reduced, and thus the probability of the hidden cracks in the solar cell assembly 110 is lowered. In a possible embodiment, the distance between any two adjacent solar cell groups 111 is 3 mm.

In the present disclosure, by limiting the distance between any two adjacent solar cell groups 111 to within the range of 3 mm to 20 mm, the difficulty in the deformation of the solar cell assembly 110 can be reduced while ensuring the overall rigidity of the solar module 100, and thus the probability of the hidden cracks in the solar cell assembly 110 is lowered. As a result, the yield rate of the solar module 100 as well as the stability and the reliability of the product are improved.

In some embodiments, each of the plurality of solar cells 112 has a curved surface.

In this embodiment, the solar cell 112 is further limited. Specifically, each of the solar cell 112, the first protective layer 120, and the second protective layer 130 has a curved surface. Thus, the solar module 100 is formed as a curved product. In this way, it is possible to not only improve aesthetically pleasing of the solar module 100 but also make the solar module 100 applicable to more types of photovoltaic apparatuses.

In some embodiments, as shown in FIG. 6, the solar module 100 further includes a first adhesive film layer 140 and a second adhesive film layer 150. The first adhesive film layer 140 is located between the solar cell assembly 110 and the first protective layer 120. The first adhesive film layer 140 is configured to bond the solar cell assembly 110 and the first protective layer 120. The first adhesive film layer 140 is light-transmissive. The second adhesive film layer 150 is located between the solar cell assembly 110 and the second protective layer 130. The second adhesive film layer 150 is configured to bond the solar cell assembly 110 and the second protective layer 130.

In this embodiment, the structure of the solar module 100 is further limited. The solar module 100 further includes the first adhesive film layer 140 and the second adhesive film layer 150. The first adhesive film layer 140 and the second adhesive film layer 150 are configured to bond the first protective layer 120, the solar cell assembly 110, and the second protective layer 130 into one piece. Specifically, the first adhesive film layer 140 is located between the solar cell assembly 110 and the first protective layer 120 and is configured to bond the solar cell assembly 110 and the first protective layer 120. Moreover, since the first adhesive film layer 140 is light-transmissive, the light can pass through the first protective layer 120 and the first adhesive film layer 140 to reach the solar cell assembly 110, enabling the solar cell assembly 110 to convert the light energy into the electrical energy and thus generate the power. The second adhesive film layer 150 is located between the solar cell assembly 110 and the second protective layer 130 and is configured to bond the solar cell assembly 110 and the second protective layer 130.

Each of the first adhesive film layer 140 and the second adhesive film layer 150 may be made of ethylene vinyl acetate polymer (EVA), polyethylene (POE), polyvinyl butyral (PVB), or organic silicone or the like.

By providing the first adhesive film layer 140 and the second adhesive film layer 150 in the solar module 100, the first protective layer 120 and the solar cell assembly 110 can be bonded by the first adhesive film layer 140, and the second protective layer 130 and the solar cell assembly 110 can be bonded by the second adhesive film layer 150. Thus, the first protective layer 120, the solar cell assembly 110, and the second protective layer 130 are formed into a whole.

In some embodiments, the second surface 114 is capable of receiving light, and the second protective layer 130 and the second adhesive film layer 150 are light-transmissive.

In this embodiment, the solar cell assembly 110, the second protective layer 130, and the second adhesive film layer 150 are further limited. Specifically, the second surface 114 of the solar cell assembly 110 is capable of receiving light, and the second protective layer 130 and the second adhesive film layer 150 are light-transmissive. In this way, the light can pass through the second protective layer 130 and the second adhesive film layer 150, and then reach the second surface 114 of the solar cell assembly 110. Since the second surface 114 of the solar cell assembly 110 is capable of receiving light, the solar cell assembly 110 can achieve bifacial power generation.

By configuring the second protective layer 130 and the second adhesive film layer 150 to be light-transmissive and the second surface 114 of the solar cell assembly 110 to be capable of receiving light, the solar cell assembly 110 can achieve the bifacial power generation, making the solar module 100 a bifacial power generation product.

A second aspect of the present disclosure also provides a photovoltaic apparatus. The photovoltaic apparatus includes the solar module 100 according to the first aspect of the present disclosure.

The photovoltaic apparatus according to the second aspect of the present disclosure includes the solar module 100 according to the first aspect of the present disclosure, and thus has all the beneficial effects of the solar module 100.

In a possible embodiment, as shown in FIG. 6, the photovoltaic product (i.e., the solar module 100) includes a curved tempered glass (the first protective layer 120), a first encapsulation adhesive film (i.e., the first adhesive film layer 140), a power generation unit (i.e., the solar cell assembly 110), a second encapsulation adhesive film (i.e., the second adhesive film layer 150) and a rear cover plate (i.e., the second protective layer 130). The above components are sequentially stacked to form the photovoltaic product, and bonding and molding between the layers are realized through the first encapsulation adhesive film and the second encapsulation adhesive film. The rear cover plate may be made of tempered glass or a PET material and has certain weather resistance. The first encapsulation adhesive film and the second encapsulation adhesive film may be made of materials such as EVA, POE, PVB, or organic silicone. The power generation unit is a crystalline silicon solar cell.

As shown in FIG. 1, most photovoltaic products 2′ in related art adopt a vacuum bag lamination process. During a lamination, pressure is applied to the photovoltaic product 2′ by two layers of silicone bags (i.e., a lamination component 1′) under vacuum negative pressure, and the encapsulation adhesive film is melted by heating to bond the material of each layer together. At a position of the photovoltaic product 2′, due to the vacuum negative pressure and pressure caused by deformation of the silicone bag, stress on an edge of the product is greater than that at other positions of the product. The solar cell at the edge position is prone to the hidden cracks due to the excessive stress.

As shown in FIG. 7, the power generation unit includes a plurality of battery strings (i.e., the solar cell groups 111), and any one of the plurality of battery strings includes a plurality of solar cells 112. Each of the plurality of solar cells 112 may be a crystalline silicon solar cell, which is applied in the curved photovoltaic product. The solar cell 112 needs to be bent on a curved rear cover plate and a curved tempered glass. Different cell spacing (i.e., the spacing between the adjacent solar cells 112), string spacing (i.e., the spacing between the adjacent solar cell groups 111), and distance from the battery string to an edge of the curved tempered glass (i.e., the distance from the solar cell group 111 to the edge of the first protective layer 120) all have a certain impact on the hidden cracks of the solar cell 112.

The cell spacing mainly affects a situation where the solar cells 112 may come into contact with each other during bending conformity, leading to contact-induced hidden cracks. As shown in FIGS. 2 and 3, an overlapping dimension D2 between two adjacent solar cells 112 in the photovoltaic product ranges from 0 mm to 0.5 mm (as shown in FIG. 2), or a spacing D3 between two adjacent solar cells 112 ranges from 0 mm to 5 mm (as shown in FIG. 3). As shown in FIG. 7, in the photovoltaic product according to the present disclosure, a spacing D3 between two adjacent solar cells 112 is 0.5 mm.

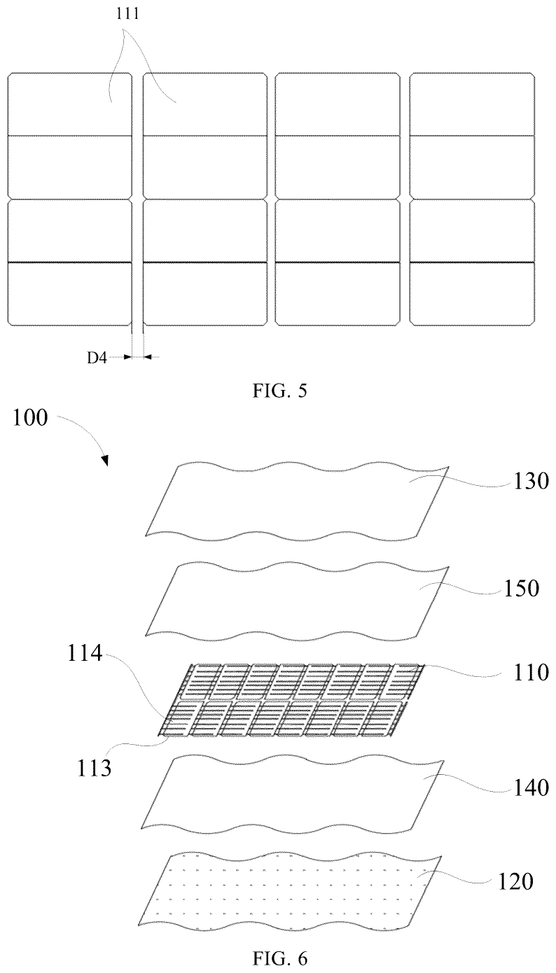

The string spacing mainly affects the overall rigidity of the solar cell 112. Rigidity of a battery string group increases as the spacing decreases, making it more difficult to conform to the curved surface. Conversely, the overall rigidity of the battery string group decreases as the string spacing increases, making it easier to conform to the curved surface. As shown in FIGS. 4 and 5, a spacing D4 between two adjacent battery strings in the photovoltaic product ranges from 3 mm to 20 mm. As shown in FIG. 7, in a possible embodiment, in the photovoltaic product according to the present disclosure, the spacing D4 between the two adjacent battery strings is 3 mm.

A distance between the battery string and an edge of the product mainly affects stress on the solar cell 112 at the edge of the product. The stress on the solar cell 112 at the edge of the product decreases as the distance between the battery string and an edge of the product increases. Conversely, the stress on the solar cell 112 at the edge of the product increases as the distance between the battery string and an edge of the product decreases. A distance between the battery string of the photovoltaic product and an edge of the curved tempered glass ranges from 10 mm to 50 mm. As shown in FIG. 7, in a possible embodiment, in the photovoltaic product according to the present disclosure, a distance D1 between the battery string and the edge of the curved tempered glass is 25 mm.

A third aspect of the present disclosure provides a method for processing a solar module. The solar module is laminated by a laminator, and the laminator includes a plurality of lamination components. As shown in FIG. 8, it is a first schematic flowchart of a method for processing a solar module according to an embodiment of the present disclosure. The method includes operations at blocks S102 and S104.

At block S102, a first protective layer, a first adhesive film layer, a solar cell assembly, a second adhesive film layer, and a second protective layer are sequentially stacked between the plurality of lamination components in a top-to-bottom direction. Each of the first protective layer and the second protective layer has a curved surface. The solar cell assembly and the first protective layer are projected onto a projection plane in a stacking direction. On the projection plane, a projection area of the solar cell assembly is located within a projection area of the first protective layer with a distance D1 between an edge of the solar cell assembly and an edge of the first protective layer adjacent to the edge of the solar cell assembly ranging from 10 mm to 50 mm.

At block S104, the first protective layer, the first adhesive film layer, the solar cell assembly, the second adhesive film layer, and the second protective layer are laminated by the plurality of lamination components to form the solar module.

The method for processing the solar module according to the present disclosure is used to process the solar module. The solar module is laminated by the laminator, and the laminator includes the plurality of lamination components. The laminator is configured to apply pressure to the first protective layer, the first adhesive film layer, the solar cell assembly, the second adhesive film layer, and the second protective layer through the plurality of lamination components to form the solar module. Specifically, the first protective layer, the first adhesive film layer, the solar cell assembly, the second adhesive film layer, and the second protective layer are sequentially stacked between the plurality of lamination components in a top-to-bottom direction. Then, the first protective layer, the first adhesive film layer, the solar cell assembly, the second adhesive film layer, and the second protective layer are laminated by the lamination components to form the solar module. During the lamination, the first protective layer is bonded to the first surface of the solar cell assembly through the first adhesive film layer, and the second protective layer is bonded to the second surface of the solar cell assembly through the second adhesive film layer, to form the solar module. Further, each of the first protective layer and the second protective layer has the curved surface, and the solar cell assembly, the first protective layer, and the second protective layer are laminated by the silicone bag laminator to form the solar module 100. Since each of the first protective layer and the second protective layer has the curved surface, the solar cell assembly is deformed along with bending of the surfaces of the first protective layer and the second protective layer during the lamination. The solar cell assembly is prone to hidden cracks after being deformed under pressure. In order to lower a probability of hidden cracks in the solar cell, the present disclosure defines a size relationship between the solar cell assembly and the first protective layer is limited in the present disclosure.

Specifically, the solar cell assembly and the first protective layer are projected onto the projection plane in the stacking direction. On the projection plane, the projection area of the solar cell assembly is located within the projection area of the first protective layer with the distance D1 between the edge of the solar cell assembly and the edge of the first protective layer adjacent to the edge of the solar cell assembly ranging from 10 mm to 50 mm. It can be understood that stress on an edge of the solar cell assembly is related to a distance between a solar cell group and the edge of the first protective layer adjacent to the solar cell group. The stress on the edge of the solar cell assembly decreases as the distance between the solar cell group and the edge of the first protective layer adjacent to the solar cell group increases, and the stress on the edge of the solar cell assembly increases as the distance between the solar cell group and the edge of the first protective layer adjacent to the solar cell group decreases. By limiting the distance between any solar cell group and the edge of the first protective layer adjacent to any solar cell group to within the range of 10 mm to 50 mm, the stress on the edge of the solar cell assembly can be reduced, and thus the probability of the hidden cracks in the solar cell assembly can be lowered. In a possible embodiment, the distance between any solar cell group and the edge of the first protective layer adjacent to any solar cell group is 25 mm.

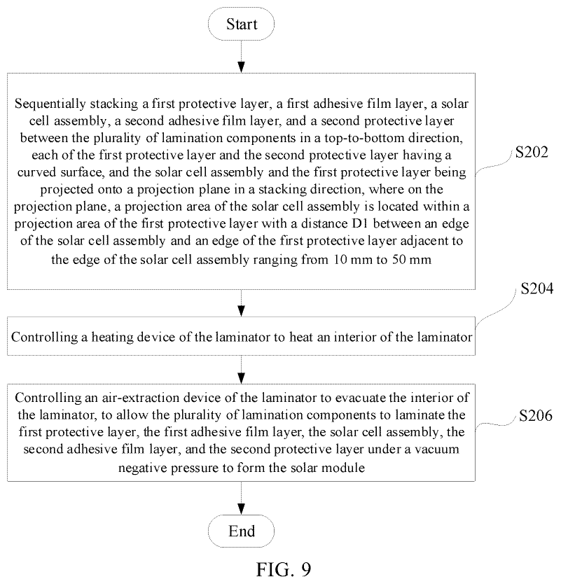

In the present disclosure, by limiting the distance between any solar cell group and the edge of the first protective layer adjacent to any solar cell group to within the range of 10 mm to 50 mm, the stress on the edge of the solar cell assembly can be reduced, and thus the probability of the hidden cracks in the solar cell assembly can be lowered. As a result, the yield rate of the solar module as well as the stability and the reliability of the product are improved. As shown in FIG. 9, it is a second schematic flowchart of a method for processing a solar module according to an embodiment of the present disclosure. The processing method includes operations at blocks S202 to S206.

At block S202, a first protective layer, a first adhesive film layer, a solar cell assembly, a second adhesive film layer, and a second protective layer are sequentially stacked between the plurality of lamination components in a top-to-bottom direction. Each of the first protective layer and the second protective layer has a curved surface. The solar cell assembly and the first protective layer are projected onto a projection plane in a stacking direction. On the projection plane, a projection area of the solar cell assembly is located within a projection area of the first protective layer with a distance D1 between an edge of the solar cell assembly and an edge of the first protective layer adjacent to the edge of the solar cell assembly ranging from 10 mm to 50 mm.

At block S204, a heating device of the laminator is controlled to heat an interior of the laminator.

At block S206, an air extraction device of the laminator is controlled to evacuate the interior of the laminator, to allow the plurality of lamination components to laminate the first protective layer, the first adhesive film layer, the solar cell assembly, the second adhesive film layer, and the second protective layer under a vacuum negative pressure, to form the solar module.

In this embodiment, the step of laminating the first protective layer, the first adhesive film layer, the solar cell assembly, the second adhesive film layer, and the second protective layer by the plurality of lamination components is limited. Specifically, the heating device of the laminator is controlled to heat the interior of the laminator first, and then the air extraction device of the laminator is controlled to evacuate the interior of the laminator, to allow the plurality of lamination components to laminate the first protective layer, the first adhesive film layer, the solar cell assembly, the second adhesive film layer, and the second protective layer under the vacuum negative pressure. The first adhesive film layer and the second adhesive film layer are melted after being heated, and then the first protective layer and the second protective layer are respectively bonded to two sides of the solar cell assembly through the first adhesive film layer and the second adhesive film layer under the pressure of the plurality of lamination components to form the solar module.

In some embodiments, as shown in FIG. 7, the solar cell assembly 110 includes a plurality of solar cell groups 111. Any one of the plurality of solar cell groups 111 includes a plurality of solar cells 112. For each of the plurality of solar cell groups 111: two adjacent solar cells 112 overlap each other with an overlapping dimension D2 ranging from 0 mm to 0.5 mm, or two adjacent solar cells 112 are spaced apart by a spacing D3 ranging from 0 mm to 5 mm; and a distance D4 between any two adjacent solar cell groups 111 ranges from 3 mm to 20 mm.

In this embodiment, the structure and the related size of the solar cell assembly 110 are limited. The solar cell assembly 110 includes the plurality of solar cell groups 111. Any one of the plurality of solar cell groups 111 includes the plurality of solar cells 112. For each of the plurality of solar cell groups 111: the two adjacent solar cells 112 overlap each other with the overlapping dimension D2 ranging from 0 mm to 0.5 mm; or the two adjacent solar cells 112 are spaced apart by the spacing D3 ranging from 0 mm to 5 mm. The solar cell 112 may be a crystalline silicon solar cell. In a possible embodiment, the plurality of solar cell groups 111 are sequentially arranged in a first direction, and the plurality of solar cells 112 in any one of the plurality of solar cell groups 111 are sequentially arranged in a second direction perpendicular to the first direction. The solar module 100 according to the present disclosure may be processed by the silicone bag laminator. Specifically, the silicone bag laminator includes a plurality of lamination components. When processing the solar module 130 are sequentially stacked between the plurality of lamination components. Under the action of vacuum negative pressure, the plurality of lamination components apply opposite pressure to the first protective layer 120, the solar cell assembly 110 and the second protective layer 130 to laminate the first protective layer 120, the solar cell assembly 110, and the second protective layer 130. The solar cells 112 in the solar cell assembly 110 are prone to the hidden cracks after being deformed under the pressure. In order to lower the probability of the hidden cracks in the solar cells 112, a distance between individual solar cells 112 in the solar cell assembly 110 is limited in the present disclosure.

Further, for each of the plurality of solar cell groups, the two adjacent solar cells 112 overlap each other or have the spacing. Specifically, when the two adjacent solar cells 112 overlap each other, an overlapping dimension D2 between the two adjacent solar cells 112 ranges from 0 mm to 0.5 mm. When the two adjacent solar cells 112 spaced apart by a spacing D3, D3 ranges from 0 mm to 5 mm. By limiting the size of the overlapping part between the two adjacent solar cells 112 to within 0 mm to 0.5 mm, or limiting the spacing between the two adjacent solar cells 112 to within 0 mm to 5 mm, the probability of the hidden cracks in the solar cells 112 due to the stress can be lowered. In a possible embodiment, the distance between any two adjacent solar cells 112 is 0.5 mm.

Furthermore, a distance D4 between any two adjacent solar cell groups 111 ranges from 3 mm to 20 mm. It can be understood that overall rigidity of the solar cell assembly 110 is related to the spacing between the two adjacent solar cell groups 111. As the spacing between the two adjacent solar cell groups 111 decreases, the rigidity of the solar cell assembly 110 increases, making it more difficult for the solar cell assembly 110 to deform along with the surface of the first protective layer and the surface of the second protective layer 130. Conversely, as the spacing between the two adjacent solar cell groups 111 increases, the rigidity of the solar cell assembly 110 decreases, making it easier for the solar cell assembly 110 to deform along with the surface of the first protective layer 120 and the surface of the second protective layer 130. By limiting the distance between any two adjacent solar cell groups 111 to within the range of 3 mm to 20 mm, the rigidity of the solar cell assembly 110 can meet processing requirements. While ensuring the overall rigidity of the solar module 100, the difficulty in the deformation of the solar cell assembly 110 is reduced, and thus the probability of the hidden cracks in the solar cell assembly 110 is lowered. In a possible embodiment, the distance between any two adjacent solar cell groups 111 is 3 mm.

By limiting the size of the overlapping part between the two adjacent solar cells 112 to within the range of 0 mm to 0.5 mm, or limiting the spacing between the two adjacent solar cells 112 to within the range of 0 mm to 5 mm, the solar cell 112 is prevented from being subjected to excessive local stress, and thus the probability of the hidden cracks in the solar cell 112 is lowered. As a result, the yield rate of the solar module 100 as well as the stability and the reliability of the product are improved. By limiting the distance between any two adjacent solar cell groups 111 to within the range of 2 mm to 5 mm, the difficulty in the deformation of the solar cell assembly 100 can be reduced while ensuring the overall rigidity of the solar module 100, and thus the probability of the hidden cracks in the solar cell assembly 110 is lowered. As a result, the yield rate of the solar module 100 as well as the stability and the reliability of the product are improved.

In the description of this specification, descriptions with reference to the terms “an embodiment”, “some embodiments”, “an exemplary embodiment”, “an example”, “a specific example”, or “some examples” etc., mean that specific features, structure, materials or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or more embodiments or examples in a suitable manner.

Although embodiments of the present disclosure have been illustrated and described, it is conceivable for those of ordinary skill in the art that various changes, modifications, replacements, and variations can be made to these embodiments without departing from the principles and spirit of the present disclosure. The scope of the present disclosure shall be defined by the claims as appended and their equivalents.

What is claimed is:

1. A solar module, comprising:
a solar cell assembly configured to convert light energy into electrical energy, the solar cell assembly having a first surface and a second surface opposite to each other, the first surface being capable of receiving light;
a first protective layer, the first protective layer being light-transmissive, the first surface of the solar cell assembly facing towards the first protective layer, and the first protective layer having a curved surface; and
a second protective layer, the second surface of the solar cell assembly facing towards the second protective layer, the first protective layer, the solar cell assembly, and the second protective layer being sequentially stacked together, and the second protective layer having a curved surface,
wherein the solar cell assembly and the first protective layer are projected onto a projection plane in a stacking direction, wherein on the projection plane, a projection area of the solar cell assembly is located within a projection area of the first protective layer with a distance D1 between an edge of the solar cell assembly and an edge of the first protective layer adjacent to the edge of the solar cell assembly ranging from 10 mm to 50 mm.

2. The solar module according to claim 1, wherein the solar cell assembly comprises a plurality of solar cell groups, any one of the plurality of solar cell groups comprising a plurality of solar cells, wherein for each of the plurality of solar cell groups:
two adjacent solar cells overlap each other with an overlapping dimension D2 ranging from 0 mm to 0.5 mm; or
two adjacent solar cells are spaced apart by a spacing D3 ranging from 0 mm to 5 mm.

3. The solar module according to claim 2, wherein a distance D4 between any two adjacent solar cell groups among the plurality of solar cell groups ranges from 3 mm to 20 mm.

4. The solar module according to claim 2, wherein each of the plurality of solar cells has a curved surface.

5. The solar module according to claim 1, further comprising:
a first adhesive film layer located between the solar cell assembly and the first protective layer, the first adhesive film layer being configured to bond the solar cell assembly and the first protective layer, and the first adhesive film layer being light-transmissive; and
a second adhesive film layer located between the solar cell assembly and the second protective layer, the second adhesive film layer being configured to bond the solar cell assembly and the second protective layer.

6. The solar module according to claim 5, wherein:
the second surface is capable of receiving light; and
the second protective layer and the second adhesive film layer are light-transmissive.

7. The solar module according to claim 1, wherein:
the first protective layer is made of tempered glass; and
the second protective layer is made of tempered glass or polyester resin.

8. The solar module according to claim 2, wherein:
the plurality of solar cell groups are sequentially arranged in a first direction; and
the plurality of solar cells in any one of the plurality of solar cell groups are sequentially arranged in a second direction perpendicular to the first direction.

9. The solar module according to claim 1, wherein the distance D1 is equal to 25 mm.

10. A photovoltaic apparatus, comprising a solar module, the solar module comprising:
a solar cell assembly configured to convert light energy into electrical energy, the solar cell assembly having a first surface and a second surface opposite to each other, the first surface being capable of receiving light;
a first protective layer, the first protective layer being light-transmissive, the first surface of the solar cell assembly facing towards the first protective layer, and the first protective layer having a curved surface; and
a second protective layer, the second surface of the solar cell assembly facing towards the second protective layer, the first protective layer, the solar cell assembly, and the second protective layer being sequentially stacked together, and the second protective layer having a curved surface,
wherein the solar cell assembly and the first protective layer are projected onto a projection plane in a stacking direction, wherein on the projection plane, a projection area of the solar cell assembly is located within a projection area of the first protective layer with a distance D1 between an edge of the solar cell assembly and an edge of the first protective layer adjacent to the edge of the solar cell assembly ranging from 10 mm to 50 mm.

11. The photovoltaic apparatus according to claim 10, wherein the solar cell assembly comprises a plurality of solar cell groups, any one of the plurality of solar cell groups comprising a plurality of solar cells, wherein for each of the plurality of solar cell groups:
two adjacent solar cells overlap each other with an overlapping dimension D2 ranging from 0 mm to 0.5 mm; or
two adjacent solar cells are spaced apart by a spacing D3 ranging from 0 mm to 5 mm.

12. The photovoltaic apparatus according to claim 11, wherein a distance D4 between any two adjacent solar cell groups among the plurality of solar cell groups ranges from 3 mm to 20 mm.

13. The photovoltaic apparatus according to claim 11, wherein each of the plurality of solar cells has a curved surface.

14. The photovoltaic apparatus according to claim 10, wherein the solar module further comprises:
a first adhesive film layer located between the solar cell assembly and the first protective layer, the first adhesive film layer being configured to bond the solar cell assembly and the first protective layer, and the first adhesive film layer being light-transmissive; and
a second adhesive film layer located between the solar cell assembly and the second protective layer, the second adhesive film layer being configured to bond the solar cell assembly and the second protective layer.

15. The photovoltaic apparatus according to claim 14, wherein:
the second surface is capable of receiving light; and
the second protective layer and the second adhesive film layer are light-transmissive.

16. The photovoltaic apparatus according to claim 10, wherein:
the first protective layer is made of tempered glass; and
the second protective layer is made of tempered glass or polyester resin.

17. The photovoltaic apparatus according to claim 11, wherein:
the plurality of solar cell groups are sequentially arranged in a first direction; and
the plurality of solar cells in any one of the plurality of solar cell groups are sequentially arranged in a second direction perpendicular to the first direction.

18. A method for processing a solar module, wherein the solar module is laminated by a laminator, the laminator comprising a plurality of lamination components, the method comprising:
sequentially stacking a first protective layer, a first adhesive film layer, a solar cell assembly, a second adhesive film layer, and a second protective layer between the plurality of lamination components in a top-to-bottom direction, each of the first protective layer and the second protective layer having a curved surface, and the solar cell assembly and the first protective layer being projected onto a projection plane in a stacking direction, wherein on the projection plane, a projection area of the solar cell assembly is located within a projection area of the first protective layer with a distance D1 between an edge of the solar cell assembly and an edge of the first protective layer adjacent to the edge of the solar cell assembly ranging from 10 mm to 50 mm; and
laminating, by the plurality of lamination components, the first protective layer, the first adhesive film layer, the solar cell assembly, the second adhesive film layer, and the second protective layer to form the solar module.

19. The method for processing the solar module according to claim 18, wherein said laminating, by the plurality of lamination components, the first protective layer, the first adhesive film layer, the solar cell assembly, the second adhesive film layer, and the second protective layer comprises:
controlling a heating device of the laminator to heat an interior of the laminator; and
controlling an air extraction device of the laminator to evacuate the interior of the laminator, to allow the plurality of lamination components to laminate the first protective layer, the first adhesive film layer, the solar cell assembly, the second adhesive film layer, and the second protective layer under a vacuum negative pressure.

20. The method for processing the solar module according to claim 18, wherein the solar cell assembly comprises a plurality of solar cell groups, any one of the plurality of solar cell groups comprising a plurality of solar cells, wherein:
for each of the plurality of solar cell groups, two adjacent solar cells overlap each other with an overlapping dimension D2 ranging from 0 mm to 0.5 mm, or two adjacent solar cells are spaced apart by a spacing D3 ranging from 0 mm to 5 mm; and
a distance D4 between any two adjacent solar cell groups ranges from 3 mm to 20 mm.
